(19) United States
(12) Patent Application Publication
(10) Pub. No.: US 2025/0092491 A1
(43) Pub. Date: Mar. 20, 2025

(54) ALLOY COMPOSITION FOR CORROSION RESISTANCE

(71) Applicant: APPLIED MATERIALS, INC., Santa Clara, CA (US)

(72) Inventors: Chien-Min Liao, Santa Clara, CA (US); Chao Liu, San Jose, CA (US); Tom Cho, Los Altos, CA (US); Hyeon Geu Kim, Santa Clara, CA (US); Andrew Nguyen, San Jose, CA (US); Hari Ponnekanti, San Jose, CA (US); Mingdong Li, Santa Clara, CA (US); Changgong Wang, San Jose, CA (US); Bruce Alger, San Jose, CA (US)

(21) Appl. No.: 18/370,534

(22) Filed: Sep. 20, 2023

(51) Int. Cl. C22C 21/06; B22F 1/16; B22F 1/17; H01J 37/32; H01L 21/683; H01L 21/687

(52) U.S. Cl. CPC C22C 21/06; B22F 1/16; B22F 1/17; H01J 37/32477; H01L 21/6833; H01L 21/68757; B22F 2301/052; B22F 2303/20; B22F 2999/00

(57) ABSTRACT

Described herein is a chamber component having a body comprising one or more aluminum alloy compositions. A surface of the chamber component has an aluminum alloy composition comprising aluminum (Al), wherein the Al is included in an amount of about 85 wt % to about 98 wt %, based on total weight of the alloy composition, and magnesium (Mg), wherein the Mg is included in an amount of about 1 wt % to about 5 wt %, based on total weight of the alloy composition. The aluminum alloy composition further includes one or more additional chemical elements that form an equiaxed grain structure of an aluminum matrix of the alloy composition.

### TECHNICAL FIELD

Embodiments of the present disclosure relate, in general, to aluminum alloy compositions having improved corrosion resistance, such as for a chamber component of a process chamber. In particular, embodiments relate to aluminum alloy compositions usable for manufacturing processes of chamber components for process chambers, such as three-dimensional (3D) printing, plasma spray and texturing.

### BACKGROUND

Various manufacturing processes expose semiconductor process chamber components to high temperatures, high energy plasma, a mixture of corrosive gases, high stress, and combinations thereof. These extreme conditions may erode and/or corrode the chamber components, or may form particles/deposits on the surface of the chamber components. These deposits may increase the chamber components' susceptibility to defects. It may be advantageous to prevent and/or to remove the particles/deposits to extend the lifespan of the chamber component.

Currently, a metal alloy, such as an aluminum alloy, is frequently used in the formation of chamber components. Because of the extreme conditions of the process chamber, the metal alloy may be subject to corrosion and/or erosion.

### SUMMARY

In some embodiments of the present disclosure, an alloy composition may include Al, wherein the Al may be included in an amount of about 85 wt % to about 98 wt %, based on total weight of the alloy composition. The alloy composition may further include Mg, wherein the Mg may be included in an amount of about 1 wt % to about 5 wt %, based on total weight of the alloy composition. The alloy composition may further include one or more additional chemical elements that form an equiaxed grain structure of an aluminum matrix of the alloy composition.

In some embodiments of the present disclosure, a chamber component may include a body including one or more aluminum alloy compositions. A surface of the chamber component may have a first aluminum alloy composition of the one or more aluminum alloy compositions. The first aluminum alloy composition may include Al, wherein the Al may be included in an amount of about 85 wt % to about 98 wt %, based on total weight of the alloy composition. The first aluminum alloy composition may further include Mg, wherein the Mg may be included in an amount of about 1 wt % to about 5 wt %, based on total weight of alloy composition. The aluminum alloy composition may further include one or more additional chemical elements that form an equiaxed grain structure of an aluminum matrix of the alloy composition.

In some embodiments, a powder may include a plurality of particles each including an aluminum alloy composition. The aluminum alloy composition may include Al and a plurality of chemical elements. The powder may also include a coating on the plurality of particles, wherein the coating includes at least one of a plurality of nanoparticles or a sol-gel including at least one of B, C, Mg, Ti, nickel (Ni), manganese (Mn), chromium (Cr), iron (Fe), silicon (Si), zinc (Zn), tin (Sn), lead (Pb), nitrogen (N), oxygen (O), zirconium (Zr), niobium (Nb), lithium (Li), bismuth (Bi),fluorine (F), yttrium (Y), lanthanum (La), scandium (Sc), cerium (Ce), neodymium (Nd), gadolinium (Gd), ytterbium (Yb), or a combination thereof.

In some embodiments, a method of producing a three dimensional printed chamber component is provided. The method may include printing one or more first portions of the chamber component using a three-dimensional (3D) printer. The one or more first portions of the chamber component comprise a first aluminum alloy composition. The first aluminum alloy composition may include Al in an amount of about 85 wt % to about 98 wt %, based on total weight the first aluminum alloy composition. The first aluminum alloy composition may further include Mg in an amount of about 1 wt % to about 5 wt %, based on total weight of the first aluminum alloy composition. The first aluminum alloy composition may further include one or more additional chemical elements that form an equiaxed grain structure of an aluminum matrix of the alloy composition.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a cross sectional view of a processing chamber.

FIG. 2A depicts a bottom view of a showerhead.

FIG. 2B depicts a bottom view of a showerhead in accordance with an embodiment of the present disclosure.

FIG. 3 depicts powder used to three dimensionally print chamber components comprising a tailored aluminum alloy, in accordance with embodiments of the present disclosure.

FIG. 4 is a flow chart representing a method for producing a chamber component according to an embodiment of the present disclosure.

### DETAILED DESCRIPTION

Chamber components are used in a variety of ways during the manufacturing process of a semiconductor device. During manufacturing of a device, a chamber component in a chamber used to perform one or more processes for manufacturing of the device may be subject to a variety of conditions including exposure to a plasma, corrosive gases and/or high temperatures. Over time, exposure to such conditions can cause the chamber component to corrode and/or erode, such that the performance of the chamber component is impacted and it is replaced, or maintenance may need to be performed. The present disclosure includes various alloy compositions (e.g., aluminum alloy compositions) for a chamber component that are corrosion resistant and thus expand the lifespan of the chamber component. The aluminum alloy compositions described in embodiments are 3D printable and have improved corrosion resistance as compared to traditional aluminum alloys such as Al 6061.

Embodiments described herein are directed to new and useful aluminum alloy compositions that can be tailored for specific uses with respect to device processing (e.g., semiconductor processing). Aluminum alloy compositions may be adjusted in embodiments to improve corrosion resistance, adjust material strength, adjust hardness, adjust thermal conductivity, adjust impedance, adjust coefficient of thermal expansion, and/or other properties. In embodiments, powders are prepared that are either composed of the aluminum alloy composition or that, when used to perform 3D printing of a part using the powders, result in a 3D printed part having the aluminum alloy composition.

In embodiments, material surface properties of chamber components may be tailored by tailoring the aluminum alloy composition of the chamber components. Material surface properties may be considered, such as functional requirements associated with part geometries.

In some embodiments, multiple different aluminum alloy compositions may be used in 3D printing of chamber components and/or other parts. For example, a first aluminum alloy composition may be used to print one or more first portions of a chamber component and a second aluminum alloy composition may be used to print one or more second portions of the chamber component. A material source may be changed during the printing process to cause the first portions to have the first aluminum alloy composition and the second portions to have the second aluminum alloy composition. In one example, a surface of the chamber component that will be exposed to a plasma (e.g., a fluorine-based plasma) may have a first aluminum alloy composition that has an increased corrosion resistance and a remainder of the chamber component that will not be exposed to the plasma (e.g., an interior of the chamber component) may have a second aluminum alloy composition that is less resistant to corrosion but that has other beneficial properties, such as being less expensive, having greater material strength, and so on. This enables multiple material properties to be combined into a single part or unit. For example, the single part may have some regions that include a first aluminum alloy composition that has a first corrosion resistance, a first thermal conductivity, a first impedance, a first coefficient of thermal expansion (CTE), and so on and some regions that include a second aluminum alloy composition that has a second corrosion resistance, a second thermal conductivity, a second impedance, a second coefficient of thermal expansion (CTE), and so on. Still other regions may include a third, fourth, fifth, etc. aluminum alloy composition that has a different corrosion resistance, a different thermal conductivity, a different impedance, a different coefficient of thermal expansion (CTE), and so on. The single part or unit may not be assembled from sub-parts and may instead be printed as a single part but using different materials during 3D printing of the single part. This may result in the single part having different aluminum alloy compositions and different material properties at different regions. Accordingly, material properties may be adjusted regionally over a chamber component or other part to suit applications of the chamber component.

Embodiments enable corrosion resistance and/or other target properties (e.g., such as material strength, Young's Modulus, yield strength, tensile strength, compressive strength, shear strength, fatigue strength, toughness, hardness, ductility, electrical conductivity, electrical resistivity, dielectric constant, dielectric strength, permeability, magnetoresistance, Hall coefficient, Seebeck coefficient, thermal conductivity, thermal resistivity, CTE, specific heat capacity, and so on) to be achieved for an aluminum alloy based on one or more of composition, grain size, and a formation process of the aluminum alloy materials. An aluminum alloy and material properties such as grain size and formation process may be controlled based on a type of component being manufactured and/or an application for the component.

Embodiments provide for techniques to prepare a material source (e.g., powders) for use in 3D printing of parts such as chamber components. Embodiments additionally provide for methods of 3D printing parts such as chamber components that integrate different alloy compositions (e.g., different aluminum alloy compositions) in different regions and thus that have different material properties in different regions.

Embodiments disclosed herein cover various new aluminum compositions that have material properties that are beneficial for certain applications, such as for use in chamber components that will be exposed to plasma. Such aluminum compositions may have improved corrosion resistance and/or plasma resistance as compared to traditional aluminum alloys such as Al 6061.

Embodiments disclosed herein describe an alloy composition including aluminum (Al), wherein the Al may be included in an amount of about 85 wt % to about 99 wt %, based on total weight of the alloy composition. The alloy composition may further include magnesium (Mg), wherein the Mg may be included in an amount of about 1 wt % to about 5 wt %, based on total weight of the alloy composition. The alloy composition may further include one or more additional chemical elements that form an equiaxed grain structure of an aluminum matrix of the alloy composition. In some embodiments, the one or more additional chemical elements may include at least one of boron (B), carbon (C), titanium (Ti), zirconium (Zr), scandium (Sc), yttrium (Y), or a combination thereof. In other embodiments, the one or more additional chemical elements may include B, C, and Ti. In yet another embodiment, the one or more additional chemical elements may include Zr, Sc, Y, or a combination thereof.

In some embodiments, the Al may be included in an amount of about 85 wt %, about 88 wt %, about 90 wt %, about 91 wt %, about 92 wt %, about 93 wt %, about 94 wt %, about 95 wt %, about 96 wt %, about 97 wt %, about 98 wt %, about 99 wt %, or any value or sub-range herein, based on total weight of the alloy composition.

In some embodiments, the Mg may be included in an amount of about 1 wt %, about 1.5 wt %, about 2 wt %, about 2.5 wt %, about 3 wt %, about 3.5 wt %, about 4 wt %, about 4.5 wt %, about 5 wt %, or any value or sub-range herein, based on total weight of the alloy composition. When including Mg in the alloy composition of the present disclosure, Mg has been found to modulate anodized film porosity and homogeneity of the alloy composition.

In an embodiment, the alloy composition may include B. B may be included in an amount of about 0.1 wt % to about 3 wt %, based on total weight of the alloy composition. In some embodiments, B may be included in an amount of about 0.1 wt %, about 0.2 wt %, about 0.3 wt %, about 0.4 wt %, about 0.5 wt %, about 0.6 wt %, about 0.7 wt %, about 0.8 wt %, about 0.9 wt %, about 1 wt %, about 1.2 wt %, about 1.4 wt %, about 1.6 wt %, about 1.8 wt %, about 2 wt %, about 2.2 wt %, about 2.4 w %, about 2.6 wt %, about 2.8 wt %, about 3 wt %, or any value or sub-range herein, based on total weight of the alloy composition.

In an embodiment, the alloy composition may include C. C may be included in an embodiment of about 0.05 wt % to about 1 wt %, based on total weight of the alloy composition. In some embodiments, C may be included in an amount of about 0.05 wt %, about 0.08 wt %, about 0.1 wt %, about 0.2 wt %, about 0.3 wt %, about 0.4 wt %, about 0.5 wt %, about 0.6 wt %, about 0.7 wt %, about 0.8 wt %, about 0.9 wt %, about 1 wt %, or any value or sub-range herein, based on total weight of the alloy composition.

In an embodiment, the alloy composition may include Ti. Ti may be included in an amount of about 1 wt % to about 5 wt %, based on total weight of the alloy composition. In some embodiments, Ti may be included in an amount of about 1 wt %, about 1.5 wt %, about 2 wt %, about 2.5 wt %, about 3 wt %, about 3.5 wt %, about 4 wt %, about 4.5 wt %, about 5 wt %, or any value or sub-range herein, based on total weight of the alloy composition. Ti may be included in the alloy composition as a grain refiner. In some embodiments, Ti and B may be included in the alloy composition to enhance the grain refining effect of the alloy composition, by adding TiB₂ to the alloy composition.

In an embodiment, the alloy composition may further include at least one additional element. The at least one additional element may include at least one of nickel (Ni), manganese (Mn), chromium (Cr), iron (Fe), silicon (Si), zinc (Zn), tin (Sn), lead (Pb), nitrogen (N), oxygen (O), fluorine (F), niobium (Nb), lanthanum (La), cerium (Ce), neodymium (Nd), gadolinium (Gd), ytterbium (Yb), or a combination thereof.

In some embodiments, Fe may be included to strengthen the alloy composition. In some embodiments, Cr may be included to control the grain structure of the composition, prevent grain growth in the alloy and/or prevent recrystallization during a heat treatment in the alloy composition. In some embodiments, Cr may also reduce stress corrosion susceptibility and may improve toughness. In some embodiments, Zr may be included to the alloy composition to prevent recrystallization in the alloy composition. In some embodiments, Li may be included to the alloy composition may substantially increase strength and Young's modulus, may provide precipitation hardening and/or decrease density of the alloy composition.

In some embodiments, the at least one additional element is or includes Ni, wherein the Ni is included in an amount of about 0.2 wt % to about 1 wt %, based on total weight of the alloy composition. In some embodiments, Ni is included in an amount of about 0.2 wt %, about 0.3 wt %, about 0.4 wt %, about 0.5 wt %, about 0.6 wt %, about 0.7 wt %, about 0.8 wt %, about 0.9 wt %, or about 1 wt %, based on total weight of the alloy composition. In some embodiments, Ni may be included in the alloy composition to improve hardness and strength at high temperatures, and/or to reduce the coefficient of expansion.

In an embodiment, the alloy composition may further include at least one additional element, wherein the at least one additional element may include at least one of Fe, Cr, Ni, Ti, zirconium (Zr), lithium (Li), lead (Pb), bismuth (Bi), or a combination thereof. In some embodiments, Pb and Bi may be included to the alloy composition to aid in chip formation and improve machinability.

In an embodiment, a chamber component may include a body including one or more aluminum alloy compositions. A surface of the chamber component may have a first aluminum alloy composition of the one or more aluminum alloy compositions. The first aluminum alloy composition may include Al, Mg, and one or more additional chemical elements that form an equiaxed grain structure of an aluminum matrix of the alloy composition. In some embodiments, the one or more additional elements may include at least one of B, C, Ti, Zr, Sc, Y, or a combination thereof. The amount of Al, Mg, B, C, Ti may be included as described above in relation to the alloy composition.

In an embodiment, the first aluminum alloy composition may have a thickness of about 10 nm to about 100 μm. In some embodiments, the first aluminum alloy composition may have a thickness of about 10 nm to about 100 μm, about 50 nm to about 90 μm, about 100 nm to about 80 μm, about 150 nm to about 70 μm, about 200 nm to about 60 μm, about 250 nm to about 50 μm, about 300 nm to about 40 μm, about 350 nm to about 30 μm, about 400 nm to about 20 μm, about 500 nm to about 10 μm, or about 750 nm to about 1 μm, or any value or sub-range herein. In some embodiments, the chamber component may include a chamber lid, a shower head, a nozzle, a substrate support assembly, an electrostatic chuck, a coupon or a gas distribution plate.

In an embodiment, the one or more aluminum alloy compositions may further include a second aluminum alloy composition disposed beneath the first aluminum alloy composition. The first aluminum alloy composition may provide improved corrosion resistance on a surface of the chamber component as compared to the second aluminum alloy composition.

In an embodiment, a first section of the body of the chamber component may include a thinner layer of the first aluminum alloy composition, when compared to a second section of the body of the chamber component. In some embodiments, the first section of the body may include an outer section of the body of the chamber component. In some embodiments, the second section of the body of the chamber component may include an inner section of the body of the chamber component.

In another embodiment, a powder is provided. The powder may include a plurality of particles each including an alloy composition including Al and a plurality of chemical elements; and a coating on the plurality of particles. The coating may include at least one of a plurality of nanoparticles, or a sol-gel including at least one of B, C, Mg, Ti, Ni, Mn, Cr, Fe, Si, Zn, Sn, Pb, N, O, Zr, Nb, Li, Bi, F, Y, La, Sc, Ce, Nd, Gd, Yb, or a combination thereof.

In some embodiments, the plurality of nanoparticles may be attached to the plurality of particles through a static charge, a Van der Waals force, or a covalent bond. In an embodiment, the plurality of nanoparticles may include a metal, an alloy, an oxide, a metal oxide, a metal alloy, a nitride, a carbide, a fluoride, or a combination thereof.

In an embodiment, the plurality of nanoparticles may have a particle size of about 0.5 nm to about 400 nm. In some embodiments, the plurality of nanoparticles may have a particle size of about 0.5 nm, about 1 nm, about 5 nm, about 10 nm, about 20 nm, about 50 nm, about 80 nm, about 100 nm, about 120 nm, about 150 nm, about 180 nm, about 200 nm, about 220 nm, about 250 nm, about 280 nm, about 300 nm, about 320 nm, about 350 nm, about 380 nm, or about 400nm, or any value or sub-range herein.

In some embodiments, the aluminum alloy composition may have a melting temperature of about 450°° C. to about 700° C., about 475° C. to about 675°, about 500° C. to about 650° C., or about 550° C. to about 600° C. or any value or sub-range herein.

In some embodiments, the powder may include agglomerates of the plurality of nanoparticles and the particles. In an embodiment, the plurality of nanoparticles may be approximately uniformly distributed on the plurality of particles.

In an embodiment, the aluminum alloy composition may include Al in an amount of about 85 wt % to about 99 wt %, based on total weight of the aluminum alloy composition and Mg in an amount of about 1 wt % to about 5 wt %, based on total weight of the aluminum alloy composition. In some embodiments, the aluminum alloy composition may include Al in an amount of about 85 wt %, about 86 wt %, about 87 wt %, about 88 wt %, about 89 wt %, about 90 wt %, about 91 wt %, about 92 wt %, about 93 wt %, about 94 wt %, about 95 wt %, about 96 wt %, about 97 wt %, about 98 wt %, or about 99 wt %, based on total weight of the aluminum alloy composition; and Mg in an amount of about 1 wt %, about 1.5 wt %, about 2 wt %, about 2.5 wt %, about 3 wt %, about 3.5 wt %, about 4 wt %, about 4.5 wt %, or about 5 wt %, based on total weight of the aluminum alloy composition.

In another embodiment, a method of producing a three-dimensional printed chamber component is provided. The method may include preparing a chamber component. The method may further include depositing a first aluminum alloy composition on a surface of the chamber component, wherein the first aluminum alloy composition includes Al in an amount of about 85 wt % to about 99 wt % and Mg in an amount of about 1 wt % to about 5 wt %, based on total weight of the first aluminum alloy composition. In some embodiments, the first aluminum alloy composition may include Al in an amount of about 85 wt %, about 86 wt %, about 87 wt %, about 88 wt %, about 89 wt %, about 90 wt %, about 91 wt %, about 92 wt %, about 93 wt %, about 94 wt %, about 95 wt %, about 96 wt %, about 97 wt %, about 98 wt %, or about 99 wt %, based on total weight of the first aluminum alloy composition; and Mg in an amount of about 1 wt %, about 1.5 wt %, about 2 wt %, about 2.5 wt %, about 3 wt %, about 3.5 wt %, about 4 wt %, about 4.5 wt %, or about 5 wt %, based on total weight of the first aluminum alloy composition. In some embodiments, the first aluminum alloy composition may include one or more additional chemical elements that form an equiaxed grain structure of an aluminum matrix of the alloy composition. The one or more additional chemical elements may include at least one of B, C, Ti, Zr, Sc, Y, or a combination thereof.

In some embodiments, the method may further include depositing a second aluminum alloy composition beneath the first aluminum alloy composition (e.g., depositing the second aluminum alloy composition before depositing the first aluminum alloy composition over the second aluminum alloy composition). The first aluminum alloy composition provides improved corrosion resistance on the surface as compared to the second aluminum alloy composition.

In an embodiment, the first aluminum alloy composition may include B. B may be included in an amount of about 0.1 wt % to about 3 wt %, based on total weight of the first aluminum alloy composition. In some embodiments, B may be included in an amount of about 0.1 wt %, about 0.2 wt %, about 0.3 wt %, about 0.4 wt %, about 0.5 wt %, about 0.6 wt %, about 0.7 wt %, about 0.8 wt %, about 0.9 wt %, about 1 wt %, about 1.2 wt %, about 1.4 wt %, about 1.6 wt %, about 1.8 wt %, about 2 wt %, about 2.2 wt %, about 2.4 w %, about 2.6 wt %, about 2.8 wt %, about 3 wt %, or any value or sub-range herein, based on total weight of the first aluminum alloy composition.

In an embodiment, the first aluminum alloy composition may include C. C may be included in an embodiment of about 0.05 wt % to about 1 wt %, based on total weight of the first aluminum alloy composition. In some embodiments, C may be included in an amount of about 0.05 wt %, about 0.08 wt %, about 0.1 wt %, about 0.2 wt %, about 0.3 wt %, about 0.4 wt %, about 0.5 wt %, about 0.6 wt %, about 0.7 wt %, about 0.8 wt %, about 0.9 wt %, about 1 wt %, or any value or sub-range herein, based on total weight of the first aluminum alloy composition.

In an embodiment, the first aluminum alloy composition may include Ti. Ti may be included in an amount of about 1 wt % to about 5 wt %, based on total weight of the alloy composition. In some embodiments, Ti may be included in an amount of about 1 wt %, about 1.5 wt %, about 2 wt %, about 2.5 wt %, about 3 wt %, about 3.5 wt %, about 4 wt %, about 4.5 wt %, about 5 wt %, or any value or sub-range herein, based on total weight of the first aluminum alloy composition.

In some embodiments, the first aluminum alloy composition may further include at least one additional element including at least one of Ni, Mn, Cr, Fe, Si, Zn, Sn, Pb, N, O, F, Nb, La, Ce, Nd, Gd, Yb, or a combination thereof.

In some embodiments, the at least one additional element is Ni, wherein the Ni is included in an amount of about 0.2 wt % to about 1 wt %, based on total weight of the first aluminum alloy composition. In some embodiments, Ni is included in an amount of about 0.2 wt %, about 0.3 wt %, about 0.4 wt %, about 0.5 wt %, about 0.6 wt %, about 0.7 wt %, about 0.8 wt %, about 0.9 wt %, or about 1 wt %, based on total weight of the first aluminum alloy composition.

In another embodiment, the first aluminum alloy composition may include at least one additional element include at least one of Fe, Cr, Ni, Ti, Zr, Li, Pb, Bi, or a combination thereof.

In some embodiments, the second aluminum alloy composition may include Al in an amount of about 85 wt % to about 99 wt % and Mg in an amount of about 1 wt % to about 5 wt %, based on total weight of the second aluminum alloy composition. In some embodiments, the second aluminum alloy composition may include Al in an amount of about 85 wt %, about 86 wt %, about 87 wt %, about 88 wt %, about 89 wt %, about 90 wt %, about 91 wt %, about 92 wt %, about 93 wt %, about 94 wt %, about 95 wt %, about 96 wt %, about 97 wt %, about 98 wt %, or about 99 wt %, based on total weight of the second aluminum alloy composition; and Mg in an amount of about 1 wt %, about 1.5 wt %, about 2 wt %, about 2.5 wt %, about 3 wt %, about 3.5 wt %, about 4 wt %, about 4.5 wt %, or about 5 wt %, based on total weight of the second aluminum alloy composition. In some embodiments, the second aluminum alloy composition includes at least one additional element, which may be different then the at least one additional element of the first aluminum alloy composition.

In some embodiments, the method includes preparing a powder including a plurality of particles each including the first aluminum alloy composition having a coating on the plurality of particles, wherein the coating may include at least one of a plurality of nanoparticles, or a sol-gel.

In some embodiments, the coating may further include at least one of B, C, Mg, Ti, Ni, Mn, Cr, Fe, Si, Zn, Sn, Pb, N, O, Zr, Nb, Li, Bi, F, Y, La, Sc, Ce, Nd, Gd, Yb, or a combination thereof.

In an embodiment, the plurality of nanoparticles may be attached to the plurality of particles through a static charge, a Van der Waals force, or a covalent bond. In an embodiment, the plurality of nanoparticles are approximately uniformly distributed on to the plurality of particles.

Some embodiments are described herein with reference to chamber components and other articles installed in plasma etchers for semiconductor manufacturing. It should be understood that the articles described herein may be other structures that are exposed to plasma. Articles discussed herein may be chamber components for processing chambers such as semiconductor processing chambers. For example, the articles may be chamber components for a plasma etcher, a plasma cleaner, a plasma sputter reactor, a plasma propulsion system, or other processing chambers. The processing chambers may be used for processes in which a corrosive plasma environment having plasma processing conditions is provided. For example, the processing chamber may be a chamber for a plasma etcher or plasma etch reactor, a plasma cleaner, a plasma sputter reactor, and so forth. Examples of chamber components include a substrate support assembly, an electrostatic chuck (ESC), a ring (e.g., a process kit ring or single ring), a chamber wall, a base, a gas distribution plate, a showerhead, an electrodea nozzle, a lid, a liner, a liner kit, a shield, a plasma screen, a flow equalizer, a cooling base, a chamber viewport, a chamber lid, and so on.

In some embodiments, the articles described herein may be a ceramic article, a metal article, or a ceramic or a metal article. It should be understood that the articles discussed herein may also have improved corrosion resistance when used in process chambers for other processes such as non-plasma etchers, non-plasma cleaners, chemical vapor deposition (CVD) chambers, physical vapor deposition (PVD) chambers, plasma enhanced chemical vapor deposition (PECVD) chambers, plasma enhanced physical vapor deposition (PEPVD) chambers, plasma enhanced atomic layer deposition (PEALD) chambers, and so forth.

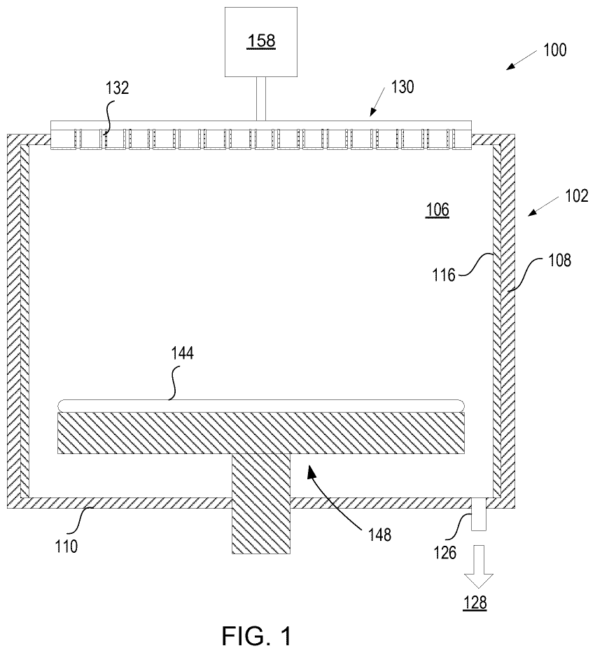

Referring now to the figures, FIG. 1 is a sectional view of a processing chamber 100 (e.g., a semiconductor processing chamber) having one or more chamber components in accordance with embodiments of the present disclosure. For example, one or more chamber components may be 3D printed parts that include one or more aluminum alloy compositions as described herein. For example, any of the described chamber components may have a first region or portion that is composed of a first aluminum alloy composition having first properties and a second region or portion that is composed of a second aluminum alloy composition having second properties. The processing chamber 100 may be used for processes in which a corrosive plasma environment and/or corrosive chemistry is provided. For example, the processing chamber 100 may be a chamber for a plasma etch reactor (also known as a plasma etcher), a plasma deposition chamber, and so on. Examples of chamber components that may be exposed to plasma in the processing chamber 100 are a substrate support assembly 148, an electrostatic chuck (ESC), a ring (e.g., a process kit ring or single ring), a chamber wall, a base, a showerhead 130, a gas distribution plate, a face plate, a liner, a liner kit, a shield, a plasma screen, a remote plasma source, a flow equalizer, a cooling base, a chamber viewport, a chamber lid, a ceramic insulator, a quartz insulator, a nozzle, process kit rings, and so on. In some embodiments, processing chamber 100 is used to perform an etch process on a patterned substrate that includes a plurality of trenches formed thereon. In other embodiments, processing chamber 100 may be used to in a deposition chamber.

In one embodiment, the processing chamber 100 includes a chamber body 102 and a showerhead 130 that enclose an interior volume 106. The showerhead 130 may or may not include a gas distribution plate. For example, the showerhead may be a multi-piece showerhead that includes a showerhead base and a showerhead gas distribution plate bonded to the showerhead base. Alternatively, the showerhead 130 may be replaced by a lid and a nozzle in some embodiments, or by multiple pie shaped showerhead compartments and plasma generation units in other embodiments. The chamber body 102 may be fabricated from nickel, copper, cobalt, chromium, molybdenum, aluminum, stainless steel, ruthenium, tungsten, platinum, or other suitable material. The chamber body 102 generally includes sidewalls 108 and a bottom 110. Any of the showerhead 130 (or lid and/or nozzle), sidewalls 108 and/or bottom 110 may include a multi-layer plasma resistant coating, or a single layer plasma resistant coating.

An outer liner 116 may be disposed adjacent the sidewalls 108 to protect the chamber body 102. The outer liner 116 may be a halogen-containing gas resist material such as Al₂O₃ or Y₂O₃. The outer liner 116 may be coated with the multi-layer plasma resistant ceramic coating in some embodiments.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The showerhead 130 may be supported on the sidewalls 108 of the chamber body 102 and/or on a top portion of the chamber body. The showerhead 130 (or lid) may be opened to allow access to the interior volume 106 of the processing chamber 100, and may provide a seal for the processing chamber 100 while closed. A gas panel 158 may be coupled to the processing chamber 100 to provide process and/or carrier gases to the interior volume 106 through the showerhead 130 or lid and nozzle. Examples of process gas that may be delivered by the gas panel 158 and used to process substrates/samples in the processing chamber 100 include a silicon containing gas, halogen-containing gases, such as C₂F₆, SF₆, HBr, NF₃, CF₄, CHF₃, CH2F3, F, NF₃, Cl₂, CCl₄, BCl₃ and SiF₄, among others, and other gases such as O₂ or N₂O. Examples of carrier gases (also referred to herein as a diluent) include N₂, He, Ar, and other gases inert to process gases (e.g., non-reactive gases). The showerhead 130 includes multiple gas delivery holes 132 throughout the showerhead 130. The showerhead 130 may be or may include aluminum, anodized aluminum, an aluminum alloy, or an anodized aluminum alloy. In some embodiments, the showerhead 130 may include the aluminum alloy composition according to the present disclosure. In some embodiments, the showerhead includes a gas distribution plate (GDP) bonded to the showerhead. The GDP may be, for example, Si or SiC, or may be a ceramic such as Y₂O₃, Al₂O₃, Y₃Al₅O₁₂ (TAG), and so forth. The GDP may additionally include multiple holes that line up with the holes in the showerhead.

For processing chambers used for conductor etch (etching of conductive materials), a lid may be used rather than a showerhead. The lid may include a center nozzle that fits into a center hole of the lid. The lid may be a ceramic such as Y₂O₃, Al₂O₃, YAG or a ceramic compound comprising Y₄Al₂O₉ and a solid-solution of Y₂O₃-ZrO₂. The nozzle may also be a ceramic, such as Y₂O₃, Al₂O₃, YAG or a ceramic compound comprising Y₄A₁₂O₉ and a solid-solution of Y₂O₃-ZrO₂.

A substrate support assembly 148 is disposed in the interior volume 106 of the processing chamber 100 below the showerhead 130. The substrate support assembly 148 holds a substrate 144 (e.g., a wafer) during processing. The substrate support assembly 148 may include an electrostatic chuck that secures the substrate 144 during processing, a metal cooling plate bonded to the electrostatic chuck, and/or one or more additional components. An inner liner may cover a periphery of the substrate support assembly 148. The inner liner may be a halogen-containing gas resist material such as A12O3 or Y2O3. The substrate support assembly, portions of the substrate support assembly, and/or the inner liner may be coated with the metal layer and barrier layer in some embodiments.

In some embodiments, the article of the present disclosure may be a chamber component, such as a substrate support assembly, an electrostatic chuck (ESC), a ring (e.g. a process kit ring or single ring), a chamber wall, a base, a gas distribution plate or showerhead, a liner, a liner kit, a shield, a plasma screen, a flow equalizer, a cooling base, a chamber viewport, a chamber lid, a face plate, a surface mount device (SMD), and so on. The body of an article may be a metal, a ceramic, a metal-ceramic composite, a polymer or a polymer-ceramic composite. In an embodiment, the body of the article may be an aluminum alloy composition of the present disclosure.

When the surfaces of a chamber component are no longer smooth, i.e., have metal fluoride deposits or particles form on it, the chamber component cannot function at optimal capacity and needs to replaced. Thus, the methods of cleaning the surface of the present disclosure may be useful in various chamber components to remove the metal fluoride deposits or particles that form on a surface of a chamber component.

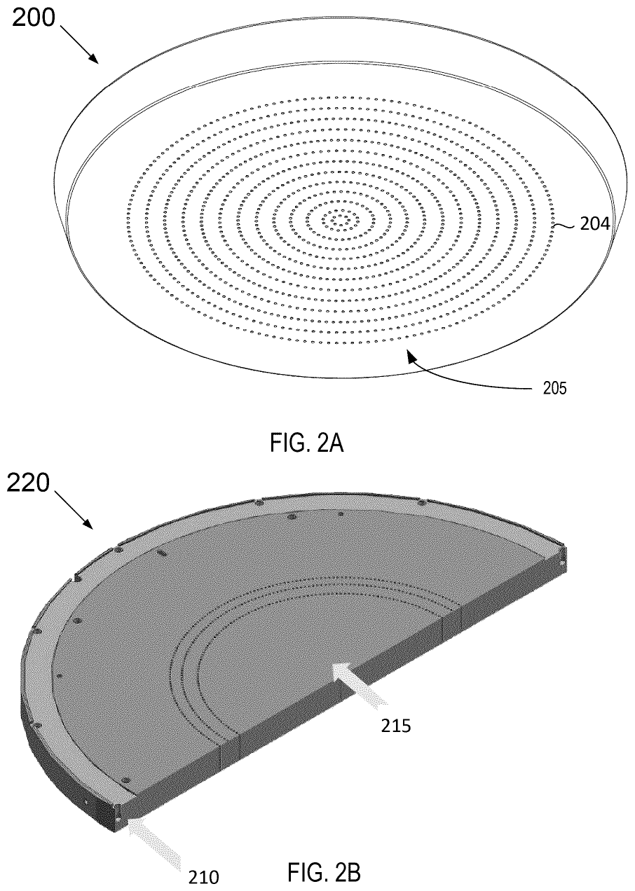

FIG. 2A illustrates one embodiment of a bottom view of a showerhead 200. The showerhead 200 may have a series of gas conduits 204 (also referred to as holes) arranged concentrically that evenly distribute plasma gasses directly over a substrate or wafer to be etched or processed. The showerhead is depicted here having approximately 1100 gas conduits 204 arranged in evenly distributed concentric rings for even distributing of gasses. In another embodiment, the gas conduits 204 may be configured in alternative geometric configurations on the lower surface 205 of the showerhead (or on a lower surface of a GDP bonded to a showerhead). For example, the showerhead may have a square or rectangular configuration having rows and columns of gas conduits 204. It is to be understood that other shapes (e.g., triangle, pentagon, etc.) may be implemented. The showerhead 200 can have many gas conduits 204, as depicted, or as few gas conduits as appropriate depending on the type of reactor and/or process utilized. In embodiments, the showerhead 200 is a 3D printed part.

In one embodiment, some or all gas conduits 204 do not include branches (e.g., each gas conduit may have a single entry point and a single exit point). Additionally, the gas conduits may have various lengths and orientation angles. Gas may be delivered to the gas conduits 204 via one or more gas delivery nozzles. Some gas conduits 204 may receive the gas before other gas conduits 204 (e.g., due to a proximity to a gas delivery nozzle). In some embodiments, one or more gas conduits 204 include branches, changing internal diameters, changes in direction, and/or other internal features that would be impractical to form via traditional manufacturing processes. In embodiments, the complex internal features of the showerhead 200 are achieved via 3D printing of the showerhead 200. The gas conduits 204 may be configured to deliver gas to a substrate resting beneath the showerhead at approximately the same time based on varying the orientation angles, diameters and/or lengths of the gas conduits 204, or by using an additional flow equalizer in embodiments. For example, gas conduits 204 that will receive gas first may be longer and/or have a greater angle (e.g., an angle that is further from 90 degrees) than conduits that will receive gas later.

FIG. 2B illustrates another embodiment of a cross-sectional view of a showerhead 220. The showerhead 220 is a single contiguous part, but different regions of the part are composed of different aluminum alloy compositions in embodiments. In particular, a first region 215 (e.g., an inner surface region) of the showerhead 220 is composed of a first aluminum alloy composition, and a second region 210 (e.g., an outer surface region and interior) of the showerhead 220 is composed of a second aluminum alloy composition. The inner portion of the showerhead is known as a process centric area, which has greater exposure to corrosive plasma, and thus where corrosive resistance is most beneficial. Thus, the showerhead 220 may be 3D printed such that the first region 215 is composed of the first alloy aluminum composition and the second region 210 may be composed of the second aluminum alloy composition. In some embodiments, the first aluminum alloy composition used for the first region 215 has increased corrosion resistance as compared to a second aluminum alloy composition used for the second region 210. The second aluminum alloy composition used for the second region 210 may have a lower thermal conductivity than the first aluminum alloy composition used for the first region 215.

In some embodiments, a thickness of the first region varies across the surface of the showerhead (e.g., such that the first region is thicker in an inner portion of the showerhead when compared to an outer portion of the showerhead). That is, the outer portion of the showerhead may include a thinner layer of the first aluminum alloy composition when compared to the inner portion of the shower head. In some embodiments, the first region 215 is thinner than the second region 210. For example, the first region may be 1-100 mm thick while the second region may be 50-500 mm thick in embodiments. In some embodiments, the first region has a thickness that is. 5%-10% of a thickness of the second region.

The first aluminum alloy composition used in the showerhead 200, 220 includes Al in an amount of about 85 wt % to about 98 wt % and Mg in an amount of about 1 wt % to about 5 wt %, based on total weight of the first aluminum alloy composition. In some embodiments, the first aluminum alloy composition may include Al in an amount of about 85 wt %, about 86 wt %, about 87 wt %, about 88 wt %, about 89 wt %, about 90 wt %, about 91 wt %, about 92 wt %, about 93 wt %, about 94 wt %, about 95 wt %, about 96 wt %, about 97 wt %, about 98 wt %, or about 99 wt %, based on total weight of the first aluminum alloy composition; and Mg in an amount of about 1 wt %, about 1.5 wt %, about 2 wt %, about 2.5 wt %, about 3 wt %, about 3.5 wt %, about 4 wt %, about 4.5 wt %, or about 5 wt %, based on total weight of the first aluminum alloy composition. In some embodiments, the first aluminum alloy composition may include one or more additional chemical elements that form an equiaxed grain structure of an aluminum matrix of the alloy composition. In some embodiments, the one or more additional chemical elements may include at least one of B, C, Ti, Zr, Sc, Y, or a combination thereof. In some embodiments, the one or more additional chemical elements may include B, C, and Ti. In another embodiment, the one or more additional chemical elements may include Zr, Sc, Y, or a combination thereof.

In an embodiment, the first aluminum alloy composition may include B. B may be included in an amount of about 0.1 wt % to about 3 wt %, based on total weight of the first aluminum alloy composition. In some embodiments, B may be included in an amount of about 0.1 wt %, about 0.2 wt %, about 0.3 wt %, about 0.4 wt %, about 0.5 wt %, about 0.6 wt %, about 0.7 wt %, about 0.8 wt %, about 0.9 wt %, about 1 wt %, about 1.2 wt %, about 1.4 wt %, about 1.6 wt %, about 1.8 wt %, about 2 wt %, about 2.2 wt %, about 2.4 w %, about 2.6 wt %, about 2.8 wt %, about 3 wt %, or any value or sub-range herein, based on total weight of the first aluminum alloy composition.

In an embodiment, the first aluminum alloy composition may include C. C may be included in an embodiment of about 0.05 wt % to about 1 wt %, based on total weight of the first aluminum alloy composition. In some embodiments, C may be included in an amount of about 0.05 wt %, about 0.08 wt %, about 0.1 wt %, about 0.2 wt %, about 0.3 wt %, about 0.4 wt %, about 0.5 wt %, about 0.6 wt %, about 0.7 wt %, about 0.8 wt %, about 0.9 wt %, about 1 wt %, or any value or sub-range herein, based on total weight of the first aluminum alloy composition.

In an embodiment, the first aluminum alloy composition may include Ti. Ti may be included in an amount of about 1 wt % to about 5 wt %, based on total weight of the alloy composition. In some embodiments, Ti may be included in an amount of about 1 wt %, about 1.5 wt %, about 2 wt %, about 2.5 wt %, about 3 wt %, about 3.5 wt %, about 4 wt %, about 4.5 wt %, about 5 wt %, or any value or sub-range herein, based on total weight of the first aluminum alloy composition.

In another embodiment, the first aluminum alloy composition may include at least one additional element include at least one of Fe, Cr, Ni, Ti, Zr, Li, Pb, Bi, or a combination thereof.

In some embodiments, the at least one additional element is Ni, wherein the Ni is included in an amount of about 0.2 wt % to about 1 wt %, based on total weight of the first aluminum alloy composition. In some embodiments, Ni is included in an amount of about 0.2 wt %, about 0.3 wt %, about 0.4 wt %, about 0.5 wt %, about 0.6 wt %, about 0.7 wt %, about 0.8 wt %, about 0.9 wt %, or about 1 wt %, based on total weight of the first aluminum alloy composition.

In another embodiment, the first aluminum alloy composition may include at least one additional element include at least one of Fe, Cr, Ni, Ti, Zr, Li, Pb, Bi, or a combination thereof.

In an embodiment, a second aluminum alloy composition may be included in the showerhead 200. The second aluminum alloy composition may include Al in an amount of about 85 wt % to about 99 wt % and Mg in an amount of about 1 wt % to about 5 wt %, based on total weight of the second aluminum alloy composition. In some embodiments, the second aluminum alloy composition may include one or more additional chemical elements including at least one of B, C, Ti, Zr, Sc, Y, or a combination thereof.

In another embodiment, the second aluminum alloy composition may include at least one additional element include at least one of Fe, Cr, Ni, Ti, Zr, Li, Pb, Bi, or a combination thereof.

In some embodiments, the at least one additional element is Ni, wherein the Ni is included in an amount of about 0.2 wt % to about 1 wt %, based on total weight of the second aluminum alloy composition.

In another embodiment, the second aluminum alloy composition may include at least one additional element include at least one of Fe, Cr, Ni, Ti, Zr, Li, Pb, Bi, or a combination thereof.

In an embodiment, the second aluminum alloy composition may include different elements than the first aluminum alloy composition.

In some embodiments, the aluminum alloy composition may be deposited using a three-dimensional printing process. The three-dimensional printing-process may enable a conformal coating of relatively uniform thickness, on the surface 205. Uniform thickness refers to having a thickness variation of less than about +/−20%, a thickness variation of +/−10%, a thickness variation of +/−5%, or a lower thickness variation when comparing the thickness of the aluminum alloy composition at one location to its thickness at another location on the film or when assessing the standard deviation achieved from the average of a plurality of thickness values from a plurality of locations on the film.

While an example component of a showerhead is shown in FIGS. 2A-2B, it should be understood that the principles discussed with reference to showerheads in FIGS. 2A-2B apply to any chamber components as well as other 3D printed parts. For example, other parts may have different regions composed of different aluminum alloy compositions, having different thicknesses, disposed at different locations, and so on.

In embodiments, powders developed for use in 3D printing applications are described. The powders may include a base aluminum or aluminum alloy powder having a coating around the base powder. The base powder may be formed from a main one or a few elements that may be shared across many different aluminum alloy formulations. The coating may include one or more additional elements that provide targeted properties for an aluminum alloy to be formed. The specific elements and amounts of those elements in the coating may be tailored for a particular application and/or for particular target properties.

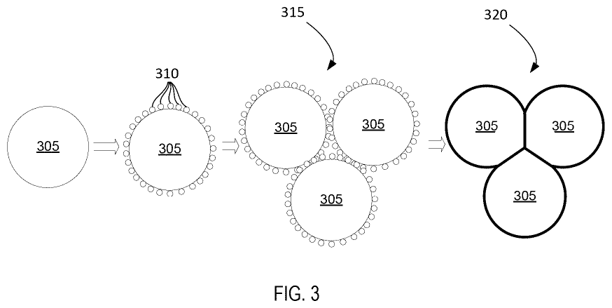

FIG. 3 depicts powder 320 that may be used to three dimensionally print chamber components comprising a tailored aluminum alloy. In embodiments, the powder 320 includes a base with controlled boundaries that have been tailored to achieve a tailored aluminum alloy composition. As can be seen in FIG. 3, a starting aluminum alloy 305 having base aluminum alloy particles 305 is used. The base aluminum alloy particles 305 may be coated with a sol-gel or a plurality of nanoparticles 310 in embodiments. FIG. 3 illustrates that the base aluminum alloy particles 305 are coated with a plurality of nanoparticles 310. The base aluminum alloy particles 305 may include, for example Al and Mg. In some embodiments, the base aluminum alloy particles 305 include Al in an amount of about 85 wt % to about 99 wt %. The base aluminum alloy particles 305 may further include Mg in an amount of about 1 wt % to about 5 wt %. The base aluminum alloy particles 305 may further include one or more additional chemical elements, wherein the one or more additional chemical elements may include at least one of boron (B), carbon (C), titanium (Ti), zirconium (Zr), scandium (Sc), yttrium (Y), or a combination thereof.

In some embodiments, the Al may be included in an amount of about 85 wt %, about 88 wt %, about 90 wt %, about 91 wt %, about 92 wt %, about 93 wt %, about 94 wt %, about 95 wt %, about 96 wt %, about 97 wt %, about 98 wt %, about 99 wt %, or any value or sub-range herein, based on total weight of the alloy composition.

In some embodiments, the Mg may be included in an amount of about 1 wt %, about 1.5 wt %, about 2 wt %, about 2.5 wt %, about 3 wt %, about 3.5 wt %, about 4 wt %, about 4.5 wt %, about 5 wt %, or any value or sub-range herein, based on total weight of the alloy composition. When including Mg in the alloy composition of the present disclosure, Mg has been found to modulate anodized film porosity and homogeneity of the alloy composition.

The plurality of nanoparticles 310 or sol-gel species may attach to the base aluminum alloy particles 305 via static charges, Van der Waals forces and/or chemical bonding in embodiments. In embodiments, the nanoparticles 310 or sol-gel species may include at least one of B, C, Mg, Ti, Ni, Mn, Cr, Fe, Si, Zn, Sn, Pb, N, O, Zr, Nb, Li, Bi, F, La, Ce, Nd, Gd, Yb, or a combination thereof, which when combined with the base aluminum alloy forms a first aluminum alloy. A plurality of the nanoparticles are attached to the plurality of particles through a static charge, a Van der Waals force, and/or a covalent bond. The plurality of nanoparticles may be approximately uniformly distributed on the plurality of particles.

In an embodiment, the nanoparticles 310 or other coating may include B. B may be included in an amount of about 0.1 wt % to about 3 wt %, based on total weight of the base particle 305 plus the nanoparticles 310 or other coating. In some embodiments, B may be included in an amount of about 0.1 wt %, about 0.2 wt %, about 0.3 wt %, about 0.4 wt %, about 0.5 wt %, about 0.6 wt %, about 0.7 wt %, about 0.8 wt %, about 0.9 wt %, about 1 wt %, about 1.2 wt %, about 1.4 wt %, about 1.6 wt %, about 1.8 wt %, about 2 wt %, about 2.2 wt %, about 2.4 w %, about 2.6 wt %, about 2.8 wt %, about 3 wt %, or any value or sub-range herein, based on total weight of the base particle 305 plus the nanoparticles 310 or other coating.

In an embodiment, the nanoparticles 310 or other coating may include C. C may be included in an embodiment of about 0.05 wt % to about 1 wt %, based on total weight of the base particle 305 plus the nanoparticles 310 or other coating. In some embodiments, C may be included in an amount of about 0.05 wt %, about 0.08 wt %, about 0.1 wt %, about 0.2 wt %, about 0.3 wt %, about 0.4 wt %, about 0.5 wt %, about 0.6 wt %, about 0.7 wt %, about 0.8 wt %, about 0.9 wt %, about 1 wt %, or any value or sub-range herein, based on total weight of the base particle 305 plus the nanoparticles 310 or other coating.

In an embodiment, the nanoparticles of other coating may include Ti. Ti may be included in an amount of about 1 wt % to about 5 wt %, based on total weight of the base particle 305 plus the nanoparticles 310 or other coating. In some embodiments, Ti may be included in an amount of about 1 wt %, about 1.5 wt %, about 2 wt %, about 2.5 wt %, about 3 wt %, about 3.5 wt %, about 4 wt %, about 4.5 wt %, about 5 wt %, or any value or sub-range herein, based on total weight of the base particle 305 plus the nanoparticles 310 or other coating.

In another embodiment, the nanoparticles 310 or other coating may include at least one additional element include at least one of Fe, Cr, Ni, Ti, Zr, Li, Pb, Bi, or a combination thereof.

In some embodiments, the at least one additional element is Ni, wherein the Ni is included in an amount of about 0.2 wt % to about 1 wt %, based on total weight of the base particle 305 plus the nanoparticles 310 or other coating. In some embodiments, Ni is included in an amount of about 0.2 wt %, about 0.3 wt %, about 0.4 wt %, about 0.5 wt %, about 0.6 wt %, about 0.7 wt %, about 0.8 wt %, about 0.9 wt %, or about 1 wt %, based on total weight of the base particle 305 plus the nanoparticles 310 or other coating.

The combined base particles 305 and nanoparticles 310 and/or coating may agglomerate to form agglomerated powder 315 in embodiments. The agglomerated powder may then be used as a powder source for 3D printing in some embodiments. During 3D printing, the agglomerated powders may fuse together to form a tailored aluminum alloy composition. In embodiments, the nano scale particles (nanoparticles 310) have a lower melting temperature than the base powder 305, and promote melting of the powder during the 3D printing process. The nanoparticle melting point depression of the nanoparticles 310 may be a few hundred degrees lower than the melting temperature of the base powder 305 in embodiments, and can reduce the temperature at which the agglomerated powder 315 melts.

In some embodiments, nanopowders 310 are selected to form a eutectic system with the base particles 305. In an eutectic system, a mixture of substances (often metals) can melt at a lower temperature than any of its constituents. This phenomenon is explained by phase diagrams, which plot the phase (solid, liquid, or gas) of a substance or mixture of substances as a function of temperature and pressure. For some mixtures, there is a specific composition that has a lower melting point than any other composition, including those of the pure constituents. This point is known as the eutectic point, and the composition is the eutectic composition. A eutectic mixture melts as a whole at a single temperature, just like a pure substance. Its melting temperature is the eutectic temperature, and it is lower than the melting temperature of any of the constituents.

In embodiments, nanoparticles 310 or sol-gel components form grain boundaries after the 3D printing process, as shown in fused nanoparticles and base particles 320. In some embodiments, the nanoparticles 310 may have a particle size of about 0.5 nm to about 400 nm, about 5 nm to abut 350 nm, about 10 nm to about 300 nm, about 25 nm to about 250 nm, about 50 nm to about 200 nm, or about 100 nm to about 150 nm.

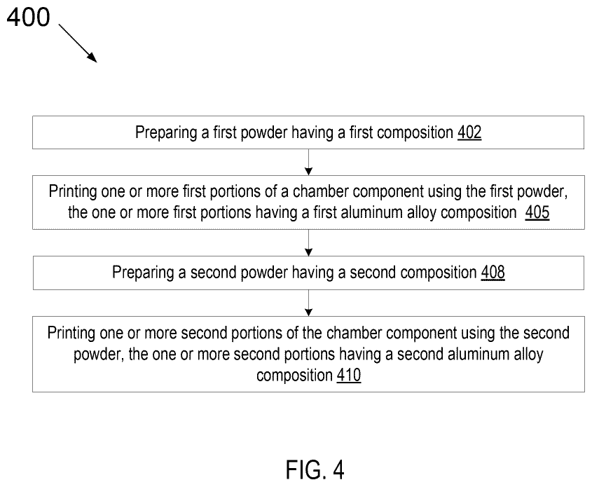

FIG. 4 is a flow chart representing a method 400 for preparing a three-dimensional printed chamber component. In the method 400, at block 402 a first powder having a first composition may be prepared. The first powder may be prepared, for example, as shown in FIG. 3. For example, the first powder may include agglomerates of a base aluminum alloy particle and one or more surrounding nanoparticles.

At block 405, printing one or more first layers and/or portions or regions of a chamber component for a process chamber is performed using a three dimensional printer The chamber component may be a chamber lid, a showerhead, a nozzle, a substrate support assembly, an electrostatic chuck, a coupon, or a gas distribution plate.

Various techniques of 3D printing may be used in embodiments. In one embodiment, Selective Laser Melting (SLM) is used to 3D print the chamber component using the first powder. In an embodiment, the SLM may be a laser-powder bed fusion device, such as L-P9F. In SLM, a high-power laser selectively melts a layer of metal powder according to a digital 3D model. After each layer is melted, a build platform on which the component is printed is lowered, and a new layer of powder is spread over the surface and melted. The process is repeated until the part is completed. SLM can produce parts with complex geometries that would be difficult or impossible to create using traditional manufacturing methods.

In one embodiment, the SLM process includes creating a 3D digital model using computer-aided design (CAD) software. This model is then converted into a series of thin layers using slicing software. The slicing software generates a path that the laser will follow during the fabrication process.

The first powder (or first material) is selected based on the target properties of a first region of the final object. The powder is placed in a 3D printer's reservoir, and a build platform is prepared. A thin layer of metal powder is spread over the build platform using a re-coater blade, roller or other device. The thickness of the layer is usually in the range of 20 to 80 micrometers, but it can vary depending on the specific machine and material.

The high-power laser scans the powder bed and selectively melts the powder according to the path generated by the slicing software. The energy from the laser is intense enough to fully melt the metal powder, causing it to solidify as a fully dense material.

Once a layer is complete, the build platform is lowered, and a new layer of powder is spread across the surface. The laser then melts the new layer, binding it to the layer below. This process is repeated, layer by layer, until the entire part is built.

Once the printing is complete, the build platform is allowed to cool. The finished part is then removed from the powder bed, often with the help of a brush or air blower. Unmelted powder is recycled for use in future builds. The part may also undergo additional post-processing steps, such as heat treatment to relieve stresses, or machining to achieve a desired surface finish or dimensional accuracy.

In some embodiments, direct metal laser sintering (DMLS) is performed to 3D print the chamber component. DMLS is similar to SLM, but instead of fully melting the metal powder, a laser heats the powder to just below its melting point, causing the particles to bond together at a molecular level. This method is typically used for metals with high melting points or alloys with different melting points.

In some embodiments, electron beam melting (EBM) is performed to 3D print the chamber component. EBM is similar to SLM but uses a focused beam of electrons instead of a laser to melt the metal powder. The EBM process takes place in a vacuum, which prevents oxidation of reactive metals like titanium.

In some embodiments, binder jetting is performed to 3D print the chamber component. In binder jetting, a binding agent is selectively deposited onto the metal powder, sticking the particles together and building the part layer by layer. After printing, the part is cured in an oven to burn off the binder and fuse the metal particles together. This method can produce parts with complex geometries and is often faster than other methods.

In some embodiments, metal fused filament fabrication (FFF) is performed to 3D print the chamber component. In this process, a filament made of metal powder mixed with a binder is extruded through a heated nozzle. After printing, the part is sintered in an oven to burn off the binder and fuse the metal particles together.

In some embodiments, directed energy deposition (DED) is performed to 3D print the chamber component. In DED, a focused energy source (like a laser or electron beam) is used to melt metal powder or wire as it's being deposited. This method is typically used for adding material to existing parts or for repair applications. In some embodiments DED or another 3D printing technique may be performed to add one or more layers of a metal alloy to an already manufactured part (e.g., to a used part). Accordingly, in embodiments 3D printing may be performed to repair a used chamber component by adding one or more layers of an aluminum alloy having tailored properties to an already manufactured chamber component.

The one or more first layers and/or portions of the chamber component may include a first aluminum alloy composition. The first aluminum alloy composition may be a composition as described above, for example the first aluminum alloy composition may correspond to that of FIG. 2B. In one embodiment, the first aluminum alloy composition is deposited to form a target thickness layer at a surface of a chamber component.

After and/or during printing one or more first layers and/or regions of a chamber component in block 405, one or more second layers and/or portions may be printed in block 410. In some embodiments, prior to printing the one or more second portions, a second powder having a second composition may be prepared at block 408. The second powder may be prepared, for example, as shown in FIG. 3. For example, the second powder may include agglomerates of a base aluminum alloy particle and one or more surrounding nanoparticles.

The one or more second layers and/or regions may be printed using the three dimensional printer. The one or more second layers and/or regions may include a second aluminum alloy composition that is different from the first aluminum alloy composition. The first aluminum alloy composition may provide improved corrosion resistance on the surface as compared to the second aluminum alloy composition in some embodiments. The second aluminum alloy composition may be a composition as described above, for example the first aluminum alloy composition may correspond to that of FIG. 2B. In one embodiment, the second aluminum alloy composition is deposited to form a second target thickness layer at a surface of the chamber component.

In some embodiments, a layer of the chamber component formed according to method 400 is composed of a single aluminum alloy composition. In some embodiments, one or more layers of the chamber component formed according to method 400 are composed of multiple different aluminum alloy compositions. For example, a first region of an area may be printed using a first powder and have a first aluminum alloy composition and a second region of the area may be printed using a second powder and have a second aluminum alloy composition. In some embodiments, different nozzles are used to deposit the different powders either one at a time or concurrently. A 3D printer may, for example, include multiple reservoirs each of which includes a different powder formulation. The 3D printer may include a different nozzle connected to the respective reservoirs or a single nozzle that connects to both reservoirs. In such an embodiment, the 3D printer may control which reservoir the nozzle is drawing powder from at any given time. If multiple nozzles are used to deposit powder, then in some embodiments both nozzles may be used to deliver powder at a same time.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

1. An alloy composition comprising:
aluminum (Al), wherein the Al is included in an amount of about 85 wt % to about 98 wt %, based on total weight of the alloy composition;
magnesium (Mg), wherein the Mg is included in an amount of about 1 wt % to about 5 wt %, based on total weight of the alloy composition; and
one or more additional chemical elements that form an equiaxed grain structure of an aluminum matrix of the alloy composition.

2. The alloy composition of claim 1, wherein the one or more additional chemical elements comprise at least one of boron (B), carbon (C), titanium (Ti), zirconium (Zr), scandium (Sc), yttrium (Y) or a combination thereof.

3. The alloy composition of claim 1, wherein the one or more additional chemicals elements comprise B, C, and Ti.

4. The alloy composition of claim 1, wherein the one or more additional chemicals elements comprise Zr, Sc, Y or a combination thereof.

5. The alloy composition of claim 1, wherein B is included in an amount of about 0.1 wt % to about 3 wt %, based on total weight of the alloy composition.

6. The alloy composition of claim 1, wherein C is included in an amount of about 0.05 wt % to about 1 wt %, based on total weight of the alloy composition.

7. The alloy composition of claim 1, wherein Ti is included in an amount of about 1 wt % to about 5 wt %, based on total weight of the alloy composition.

8. The alloy composition of claim 1, further comprising at least one additional element, wherein the at least one additional element comprises at least one of nickel (Ni), manganese (Mn), chromium (Cr), iron (Fe), silicon (Si), zinc (Zn), tin (Sn), lead (Pb), nitrogen (N), oxygen (O), fluorine (F), niobium (Nb), lanthanum (La), cerium (Ce), neodymium (Nd), gadolinium (Gd), ytterbium (Yb), or a combination thereof.

9. The alloy composition of claim 8, wherein the at least one additional element is Ni, and wherein the Ni is included in an amount of about 0.2 wt % to about 1 wt %, based on total weight of the alloy composition.

10. The alloy composition of claim 1, further comprising at least one additional element, wherein the at least one additional element comprises at least one of iron (Fe), chromium (Cr), nickel (Ni), titanium (Ti), lithium (Li), lead (Pb), bismuth (Bi), or a combination thereof.

11. A chamber component comprising:
a body comprising one or more aluminum alloy compositions, wherein a surface of the chamber component has a first aluminum alloy composition of the one or more aluminum alloy compositions, the first aluminum alloy composition comprising:
aluminum (Al), wherein the Al is included in an amount of about 85 wt % to about 98 wt %, based on total weight of the alloy composition;
magnesium (Mg), wherein the Mg is included in an amount of about 1 wt % to about 5 wt %, based on total weight of the alloy composition; and
one or more additional chemical elements that form an equiaxed grain structure of an aluminum matrix of the alloy composition.

12. The chamber component of claim 11, wherein the one or more additional chemical elements comprise at least one of boron (B), carbon (C), titanium (Ti), zirconium (Zr), scandium (Sc), yttrium (Y), or a combination thereof.

13. The chamber component of claim 11, where the first aluminum alloy composition has a thickness of about 10 nm to about 100 μm.

14. The chamber component of claim 11, wherein the chamber component comprises a chamber lid, a shower head, a nozzle, a substrate support assembly, an electrostatic chuck, a coupon or a gas distribution plate.

15. The chamber component of claim 11, wherein the one or more aluminum alloy compositions further comprises a second aluminum alloy composition disposed beneath the first aluminum alloy composition, and wherein the first aluminum alloy composition provides improved corrosion resistance on a surface of the chamber component as compared to the second aluminum alloy composition.

16. The chamber component of claim 11, wherein a first section of the body of the chamber component includes a thinner layer of the first aluminum alloy composition, when compared to a second section of the body of the chamber component.

17. The chamber component of claim 16, wherein the first section of the body comprises an outer section of the body of the chamber component, and wherein the second section of the body of the chamber component comprises an inner section of the body of the chamber component.

18. A powder comprising:
a plurality of particles each comprising an alloy composition comprising aluminum (Al) and a plurality of chemical elements; and
a coating on the plurality of particles, wherein the coating comprises at least one of a plurality of nanoparticles, or a sol-gel, comprising at least one of boron (B), carbon (C), magnesium (Mg), titanium (Ti), nickel (Ni), manganese (Mn), chromium (Cr), iron (Fe), silicon (Si), zinc (Zn), tin (Sn), lead (Pb), nitrogen (N), oxygen (O), zirconium (Zr), lithium (Li), bismuth (Bi), fluorine (F), niobium (Nb), yttrium (Y), lanthanum (La), scandium (Sc), cerium (Ce), neodymium (Nd), gadolinium (Gd), ytterbium (Yb), or a combination thereof.

19. The powder of claim 18, wherein the plurality of nanoparticles are attached to the plurality of particles through a static charge, a Van der Waals force, or a covalent bond.

20. The powder of claim 18, wherein the plurality of nanoparticles comprise a metal, an alloy, an oxide, a metal oxide, a metal alloy, a nitride, a carbide, a fluoride, or a combination thereof.

21. The powder of claim 18, wherein the plurality of nanoparticles have a particle size of about 0.5 nm to about 400 nm.

22. The powder of claim 18, wherein the aluminum alloy composition has a melting temperature of about 450° C. to about 700° C.

23. The powder of claim 18, wherein the powder comprises agglomerates of the plurality of nanoparticles and the particles.

24. The powder of claim 18, wherein the plurality of nanoparticles are approximately uniformly distributed on to the plurality of particles.

25. The powder of claim 18, wherein the aluminum alloy composition comprises aluminum (Al) included in an amount of about 85 wt % to about 99 wt %, based on total weight of the aluminum alloy composition, and magnesium (Mg) included in an amount of about 1 wt % to about 5 wt %, based on total weight of the alloy composition.

26.-38. (canceled)
